(19) United States
(12) Patent Application Publication
(10) Pub. No.: US 2011/0169520 A1
(43) Pub. Date: Jul. 14, 2011

(54) APPARATUS FOR MEASURING MINORITY CARRIER LIFETIME AND METHOD FOR USING THE SAME

(75) Inventors: G. Lorimer MILLER, Eastham, MA (US); Joseph W. FOSTER, San Jose, CA (US); David C. TIGWELL, Houston, TX (US)

(73) Assignee: MKS INSTRUMENTS, INC., ANDOVER, MA (US)

(21) Appl. No.: 12/687,855

(22) Filed: Jan. 14, 2010

(51) Int. Cl. G01R 31/26; G01R 31/00; H01F 17/06

(52) U.S. Cl. 324/762.01; 324/555; 336/178

(57) ABSTRACT

An apparatus for measuring minority carrier lifetime is provided. The apparatus includes a resonant circuit having an inductor and a capacitor and configured to resonate at a measurement frequency. The apparatus also includes a ferromagnetic core having a first portion and a second portion. The first portion defines a gap and can be configured to direct therealong a magnetic field established by the inductor, such that lateral spreading of the magnetic field outside of the first portion is inhibited, and to direct the magnetic field generally uniformly across the gap. The second portion can be configured to direct the magnetic field therealong and, in conjunction with the first portion, into a closed loop. A radiation source can be configured to irradiate an area proximal to the gap defined by the first portion of the ferromagnetic core.

### BACKGROUND

Embodiments of the present invention relate to semiconductor characterization tools, and, more particularly, to apparatuses and methods for measuring minority carrier lifetime in a semiconductor sample.

Minority carrier lifetime is a quantity of fundamental importance for semiconductor materials. This quantity can provide an indication of the quality and defect density in raw semiconductor materials, and can also be used to monitor semiconductor device fabrication and processing. In the case of device fabrication monitoring, minority carrier lifetime measurements can be performed at one or more points within a fabrication process. Each step in a fabrication process can be expensive and time consuming. As such, it may be advantageous that the material that is subjected to testing is not degraded by the testing process, which degradation could cause the material to be reworked or discarded. It may also be advantageous that such “in-line” measurements of minority carrier lifetime be relatively easily performed and understood, such that fabrication errors can be identified quickly, before time and resources are wasted performing further processing on already defective materials and before further good material is subjected to a malfunctioning fabrication process.

### SUMMARY

A novel contactless analysis system has been developed that simultaneously and in real-time provides the generation lifetime (GTAU), photo-conductance decay (PCD) and sheet conductance (σ) measurements of semiconductor materials. The unique combination of GTAU and PCD into a single analysis system provides a symbiosis that enables the analysis system and methods described here to have significant advantages over the prior art. This includes, but is not limited to, improved SNR (signal to noise ratio), the capability to measure shorter minority carrier lifetimes, and the ability to self-calibrate. The GTAU measurement is advantageous in that it is has superior SNR and has ability to measure much shorter carrier lifetimes. However, GTAU has a limitation in some applications since it is a relative measurement. This limitation is overcome by combining the PCD measurement, which is an absolute measurement, with GTAU. In this way, the (absolute) PCD measurement is used to calibrate the GTAU measurement automatically. In summary, GTAU and PCD when used in this way are complimentary, with the PCD method serving to calibrate the GTAU method results and the GTAU method then providing much higher quality measurements over a larger range of minority carrier lifetimes.

In one aspect, an apparatus, such as a minority carrier lifetime measurement tool, is provided. The apparatus can include a resonant circuit having an inductor and a capacitor and configured to resonate at a measurement frequency. The apparatus can also include a ferromagnetic core having a first portion and a second portion. The first portion can define a gap, and can be configured to direct therealong a magnetic field established by the inductor, such that lateral spreading of the magnetic field outside of the first portion is inhibited and the magnetic field is directed generally uniformly across the gap. For example, the inductor can include at least one coil that extends circumferentially around the first portion. The second portion can be configured to direct the magnetic field therealong and, in conjunction with the first portion, into a closed loop. The second portion may define a gap that is aligned with the gap defined by the first portion.

The first portion can define a longitudinal axis, and the ferromagnetic core can be generally radially symmetric about the longitudinal axis. In some embodiments, the ferromagnetic core can include opposing first and second parts, with the first part forming at least part of the first and second portions and the second part also forming at least part of the first and second portions. The first and second parts may be generally symmetrical across a plane directed along the gap defined by the first portion of the ferromagnetic core.

In some embodiments, the first and second parts may respectively include elongated bases and a central post extending from each of the elongated bases. A pair of side posts may extend from each of the elongated bases on opposing sides of, and generally parallel to, the central post, such that each of the first and second parts generally forms an “E” shape, said first portion including the central posts and the second portion including said side posts. In some embodiments, the first and second parts may respectively include generally planar bases, said first portion extends generally perpendicularly from said bases, and said second portion forms a generally annular flange extending generally perpendicularly from said bases and circumferentially around said first portion.

A radiation source can be configured to irradiate an area proximal to the gap defined by the first portion of the ferromagnetic core. For example, the radiation source can be configured to irradiate an area around the gap that is symmetric across a longitudinal axis defined by the first portion. The radiation source may include at least two light emitting diodes configured to emit radiation of respectively different wavelengths. The radiation source can include a light emitting diode that extends through one of the bases associated with the first and second parts and is disposed between the first portion and the flange formed by the second portion. In some embodiments, the radiation source may include at least two light emitting diodes that extend through respective ones of the bases and are respectively disposed between the first portion and the flange. The radiation source can include a plurality of light emitting diodes disposed circumferentially around the first portion and extending through one of the bases between the first portion and the flange, and can include another plurality of light emitting diodes similarly extending through another of the bases.

The radiation source is configured to emit radiation intermittently at a switching frequency. The apparatus may be configured to receive a sample of semiconductor material in the gap defined by the first portion of the ferromagnetic core. The radiation source can be configured to intermittently irradiate the sample with radiation configured to cause photoconductivity in the sample. The switching frequency can be on the order of or lower than the inverse of minority carrier lifetime for the sample. The resonant circuit can be associated with a measurement frequency voltage and can include a drive current source configured to provide a drive current that is adjustable so as to maintain the measurement frequency voltage across the resonant circuit constant. The apparatus may further include a data acquisition system configured to collect drive current values at times subsequent to commencing and halting irradiation of the sample by more than the inverse of minority carrier lifetime of the sample. The data acquisition system may also be configured to collect drive current values at a data collection frequency that is higher than the inverse of minority carrier lifetime for the sample and at times immediately subsequent to commencing and halting irradiation of the sample.

In another aspect, an apparatus is provided that includes a ferromagnetic core. The core can have a first portion that defines a gap and is configured to direct therealong a magnetic field established by an inductor coiled around the first portion, such that lateral spreading of the magnetic field outside of the first portion is inhibited, and to direct the magnetic field generally uniformly across the gap. A second portion of the core can be configured to direct the magnetic field there along and, in conjunction with the first portion, into a closed loop. A radiation source can be integrated into the ferromagnetic core.

In yet another aspect, a method is provided, such as a method for determining minority carrier lifetimes in semiconductor samples. The method includes providing an apparatus having a resonant circuit, a ferromagnetic core, and a radiation source. The resonant circuit can include an inductor and a capacitor and can be configured to resonate at a measurement frequency associated with a measurement frequency voltage across the resonant circuit. The ferromagnetic core can include a first portion that defines a gap and is configured to direct therealong a magnetic field established by the inductor, such that lateral spreading of the magnetic field outside of the first portion is inhibited, and to direct the magnetic field generally uniformly across the gap. The ferromagnetic core can also include a second portion configured to direct the magnetic field there along and, in conjunction with the first portion, into a closed loop. The radiation source can be configured to irradiate an area proximal to the gap defined by the first portion of the ferromagnetic core.

A sample can be electromagnetically coupled into the resonant circuit, a first portion of the sample being disposed in the gap such that a magnetic field established by the inductor extends generally uniformly through the first portion of the sample. A drive current of the resonant circuit can be adjusted to maintain constant the measurement frequency voltage. The sample can be intermittently, at a switching frequency, irradiated in an area proximal to the first portion, with radiation configured to cause photoconduction in the sample. The switching frequency can be on the order of or lower than the inverse of minority carrier lifetime for the sample.

The method may further include determining a minority carrier lifetime for the sample, for example, by measuring the drive current both while irradiating the sample and when the sample is not being irradiated. The drive current may be sampled at a sample rate that is higher than the inverse of minority carrier lifetime for the sample and at times immediately subsequent to commencing and halting irradiation of the sample. A functional approximation for temporal drive current data measured after halting irradiation of the sample and within a time equal to or longer than the inverse of minority carrier lifetime for the sample can be determined. The quasi-steady state drive current can be measured after commencing and halting irradiation of the sample to find a difference between the drive current under each set of conditions. This difference can be scaled and provided as an output.

In some embodiments, the sample can be intermittently irradiated with radiation of a first characteristic wavelength and subsequently intermittently irradiated with radiation of a second characteristic wavelength that is different from the first characteristic wavelength. In some embodiments, the sample can be repeatedly repositioned such that different portions of the sample are disposed in the gap defined by the first portion of the ferromagnetic core. The drive current can be repeatedly measured in response to each repeated repositioning of the sample.

In another aspect, an apparatus, such as a tool for measuring minority carrier lifetime in a semiconductor sample, is provided. The apparatus includes a ferromagnetic core including opposing first and second parts that define a gap therebetween. Each of said first and second parts may include a base, a generally annular flange extending from the base, and a tubular portion extending from the base and radially inside the flange. A first conductor coil can extend around the tubular portion associated with the first part, and a second conductor coil can extend around the tubular portion associated with the second part. A radiation source can be configured to irradiate at least a portion of the gap defined between said first and second parts, for example, so as to illuminate a wafer disposed in the gap. The first and second conductor coils can be configured to be connected in parallel to a variable power source, such that a magnetic field generated by the first conductor coil is generally aligned with a magnetic field generated by the second conductor coil. In some embodiments, the tubular portion may be transparent to radiation emitted from the radiation source.

### BRIEF DESCRIPTION OF THE SEVERAL VIEWS OF THE DRAWING(S)

Having thus described the invention in general terms, reference will now be made to the accompanying drawings, which are not necessarily drawn to scale.

FIG. 1 is a block diagram of a system for performing minority carrier lifetime measurements in a sample of semiconductor material.

FIG. 2 is a schematic view of a minority carrier lifetime measurement tool configured in accordance with an example embodiment.

FIG. 3 is a perspective view of a ferromagnetic core configured in accordance with an example embodiment.

FIG. 4 is a perspective view of the core of FIG. 3 sectioned along plane p of FIG. 3.

FIG. 5 is a partially exploded perspective view of the core of FIG. 4.

FIG. 6 is a top view of the core of FIG. 5 with the diffuser removed to reveal the underlying light emitting diodes.

FIG. 7 is a cross sectional view of the core of FIG. 3 sectioned along plane 7-7 of FIG. 3.

FIG. 8 is a cross sectional view of the core of FIG. 3, sectioned along plane 8-8 of FIG. 3.

FIG. 9 is a schematic view of a minority carrier lifetime measurement tool configured in accordance with another example embodiment.

FIG. 10 is a schematic cross sectional view of a core for use as part of a tool for measuring minority carrier lifetimes, the core being configured in accordance with another example embodiment.

### DETAILED DESCRIPTION

The present invention now will be described more fully hereinafter with reference to the accompanying drawings, in which some, but not all embodiments of the inventions are shown. Indeed, these inventions may be embodied in many different forms and should not be construed as limited to the embodiments set forth herein; rather, these embodiments are provided so that this disclosure will satisfy applicable legal requirements. Like numbers refer to like elements throughout.

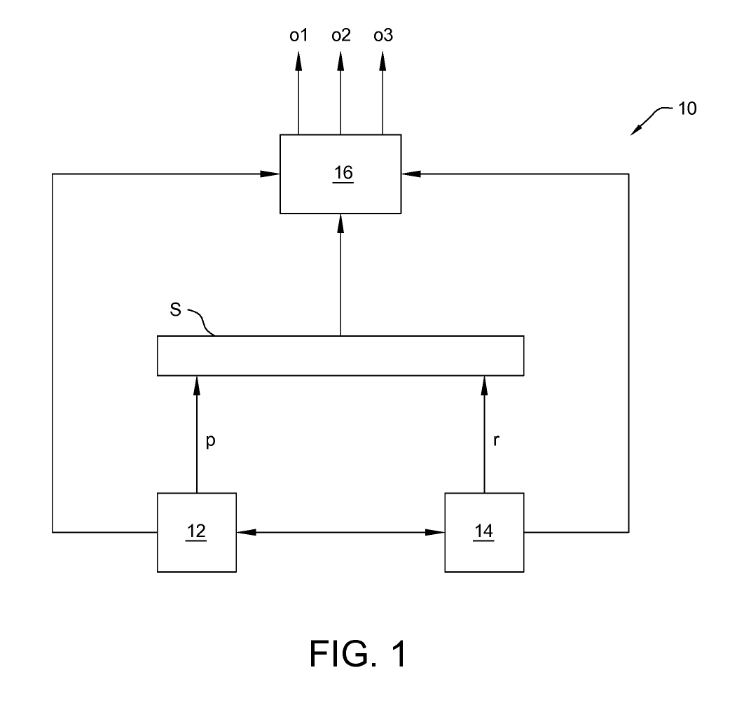

Referring to FIG. 1, therein is shown a schematic diagram of a system 10 for performing minority carrier lifetime measurements in a sample s of semiconductor material (“the sample”), the system being configured in accordance with an example embodiment. The system 10 includes a signal generation module 12 in communication with a radiation source module 14. As will be discussed further below, the signal generation module 12 acts to generate a probe signal p, for example, in the form of an oscillating electromagnetic field, with which the sample s interacts. As the sample s interacts with the probe signal p, the probe signal is attenuated by an amount related to (amongst other things) the minority carrier population in the sample. The signal generation module 12 may therefore include electrical components (both active and passive) and circuitry appropriate for generating the probe signal p. In some embodiments (discussed below), the signal generation module 12 may include structures, such as a sample interface, for effectively coupling the probe signal p and the sample s.

The radiation source module 14 may include a radiation source, such as one or more light emitting diodes (“LEDs”), for periodically irradiating r the sample s. As discussed in more detail later, some portion of the radiation r may be absorbed by the sample s, thereby causing a change in the minority carrier population in the sample. The radiation source module 14 may also include electronics for controlling the intensity of the radiation provided therefrom. For example, in some cases, the electronics associated with the radiation source module 14 may include a radiation intensity sensor and feedback circuitry that together compensate for spurious fluctuations in radiation intensity. In some embodiments (discussed below), the radiation source module 14 may be configured so as to facilitate irradiation of the sample s and effective coupling of the sample and the probe signal p.

The system 10 also includes a data collection and processing module 16 for collecting data indicative of temporal changes in the minority carrier population of the sample s. The data collection and processing module 16 is in communication with both the signal generation module 12 and the radiation source module 14, and can process the data d, including correlating the data with the probe signal p and the radiation r, in order to provide outputs o1, o2, o3 that are indicative of the minority carrier lifetime of the sample. In some cases, the data collection and processing module 16 may be at least partially integrated with the signal generation module 12, with probe signal generation and measurement of the attenuation of the probe signal (or the effort that must be expended to otherwise avoid such attenuation) being done together.

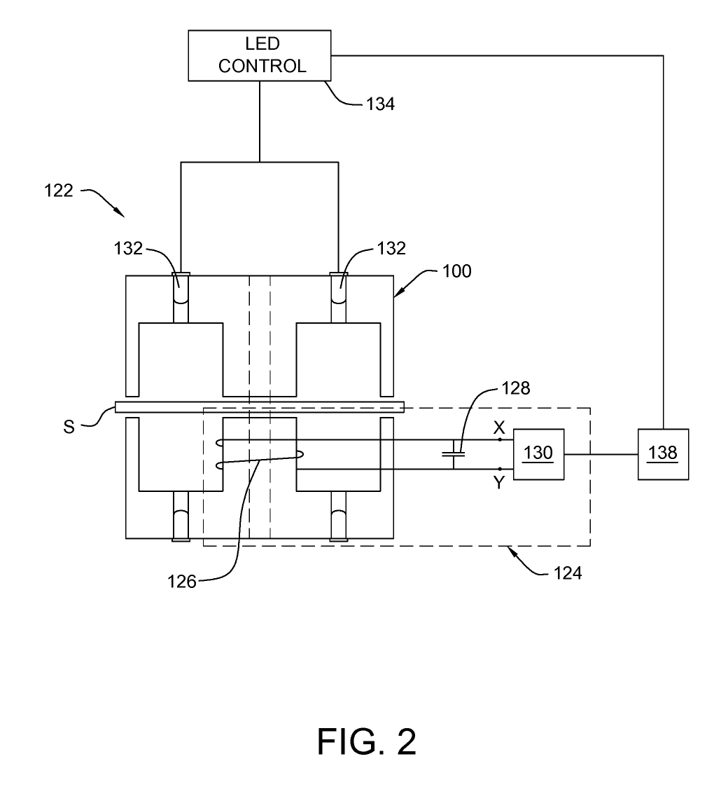

Referring to FIG. 2, therein is shown a tool 122 for measuring minority carrier lifetimes, the tool being configured in accordance with another example embodiment. The tool 122 includes a resonant circuit in the form of a marginal oscillator 124 having an inductor 126 and a capacitor 128. The marginal oscillator 124 is configured to resonate at a measurement frequency fₘ that is associated with a measurement frequency voltage. The marginal oscillator 124 may also include other circuitry and components 130, such as a voltage and/or current source, as discussed in more detail below, that facilitate operation of the marginal oscillator. The tool 122 also includes a ferromagnetic core 100, which is described below.

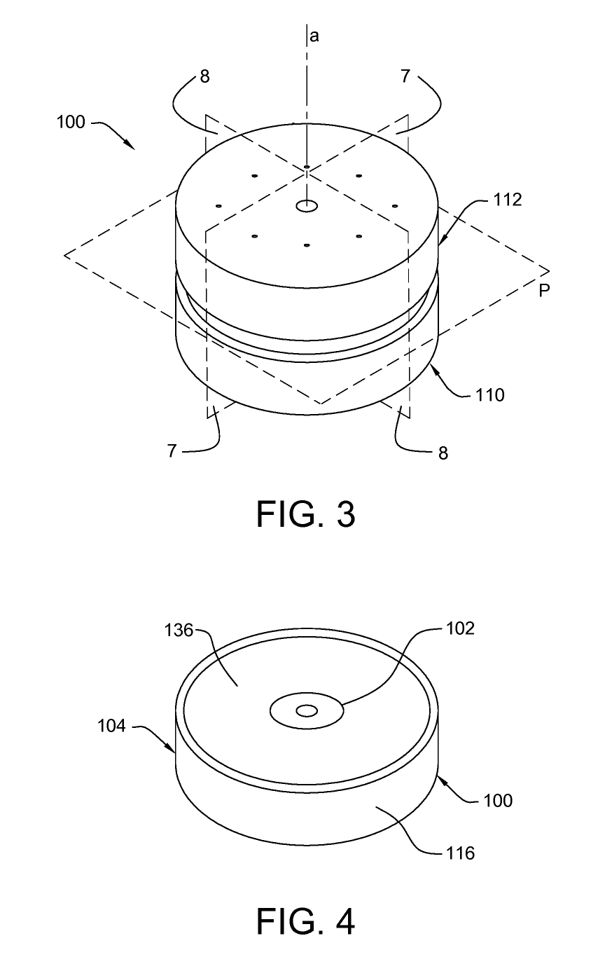

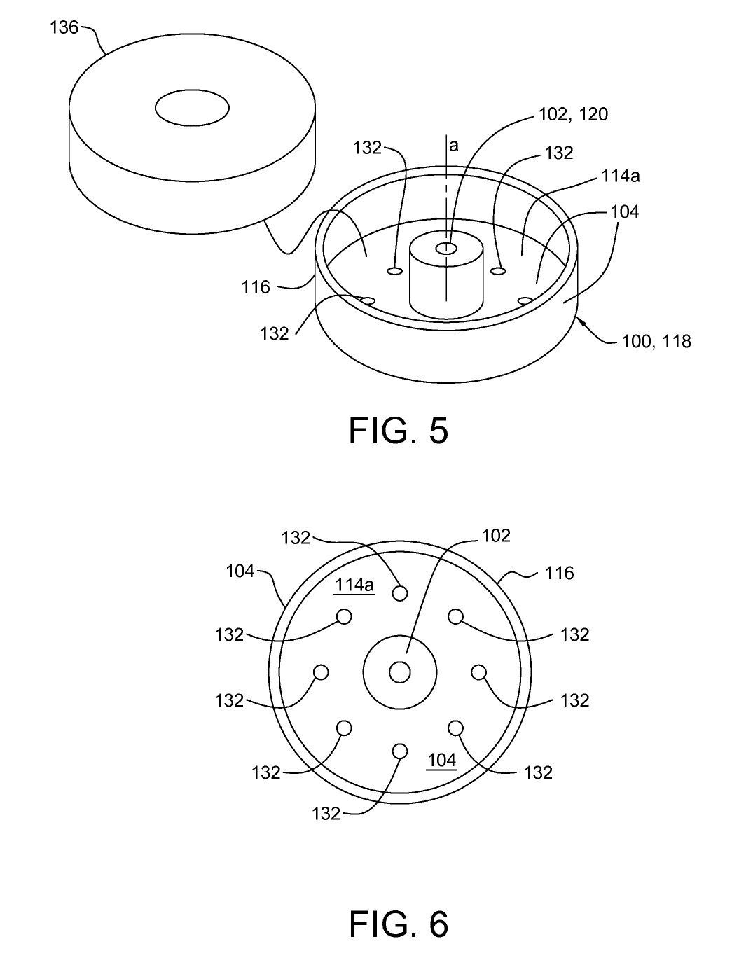

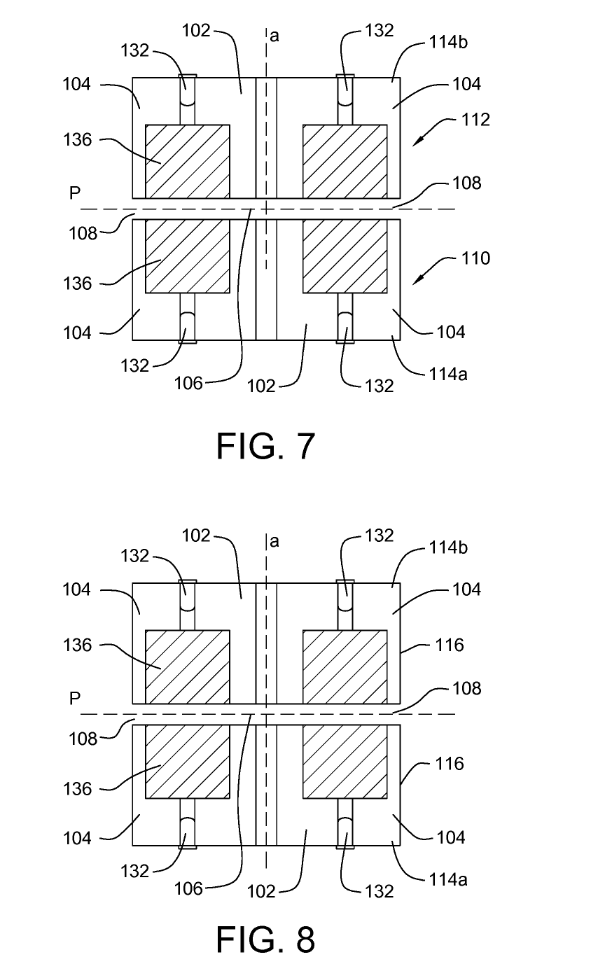

Referring to FIGS. 3-8, the ferromagnetic core 100 can have a first portion 102 and a second portion 104, with the first portion defining a gap 106. The second portion 104 may also define a gap 108 that is aligned with the gap 106 in the first portion 102. The core 100 can include opposing first 110 and second parts 112, with each of the first and second parts forming at least part of the first portion 102 and at least part of the second portion 104. In some embodiments, the first and second parts 110, 112 may be independent of one another and generally symmetrical across a plane p directed along the gap 106 (and also the gap 108). Such a configuration may allow for a sample in the form of a wafer to be disposed in the gap 106 while providing clearance for the portions of the sample that are laterally spaced apart from the portion in the gap. The core 100 may additionally, or alternatively, be generally radially symmetric about a longitudinal axis a defined by the first portion 102.

In some embodiments, the first and second parts 110, 112 may respectively include generally planar bases 114a, 114b. The first portion 102 may extend generally perpendicularly from each of the bases 114a, 114b. The second portion 104 may form a generally annular flange 116 that extends generally perpendicularly from each of the bases 114a, 114b and also circumferentially around the first portion 102. In such embodiments, each of the first and second parts 110, 112 assumes the shape of what is commonly referred to as a “pot core,” where a central post rises from a base plate and is surrounded by an annular flange. The core 100 would then be composed (at least in part) of opposing pot cores 118, with the first portion 102 including the central posts 120 of each of the pot cores and the second portion 104 including the base plates 114a, 114b and the annular flanges 116 of each of the pot cores.

Each of the first and second portions 102, 104 can be configured to respectively direct therealong a magnetic field B established by the inductor 126 when the marginal oscillator 124 is operating. For example, the inductor 126 may include at least one coil that extends circumferentially around the first portion 102. If needed, the coil can be electrostatically shielded from the first portion 102.

Referring to FIGS. 2-8, the first portion 102 may tend to inhibit lateral spreading of the magnetic field B as it is directed along the first portion and to direct the magnetic field generally uniformly across the gap 106. The second portion 104 may be configured so as to direct the magnetic field, in conjunction with the first portion 102, into a closed loop. Of course, magnetic field lines always form closed loops, whether or not any bodies or forces act to direct the field, but the first and second portions may act to specifically direct the magnetic field B in a manner the magnetic field would not otherwise experience. The first and second parts 110, 112 may be coupled to a supporting structure (not shown) that serves to hold the two parts of the core 100 in opposition to one another. The supporting structure may be formed by either a ferromagnetic or non-ferromagnetic material, and may be either conducting or insulating and in any case has little effect on the shaping of the magnetic field B by the core 100.

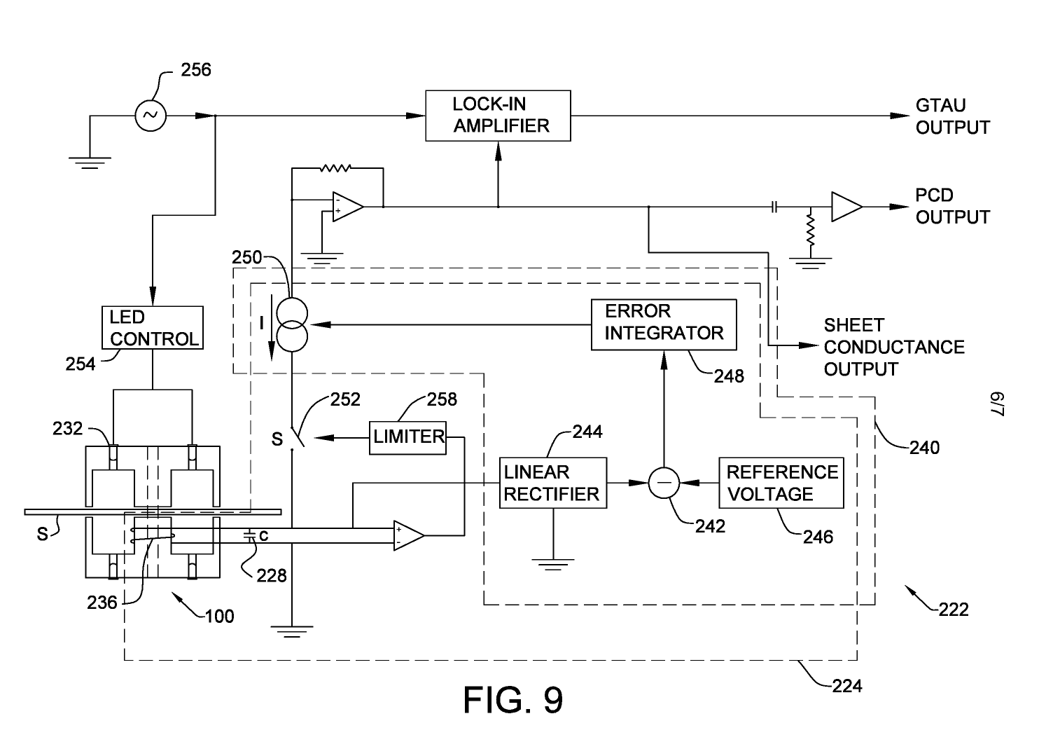

The tool 122 may further include a radiation source, such as one or more LEDs 132. The LEDs 132 can be configured to irradiate an area proximal to the gap 106 in the first portion 102. The LEDs 132 can extend through one or both of the bases 114a, 114b so as to be disposed between the first portion 102 and the flange 116. The LEDs 132 may be configured to emit radiation intermittently at a switching frequency fₛ. For example, the operation of the LEDs 132 may be controlled by an LED controller 134, which can supply power to the LEDs and can therefore control the intensity and timing (i.e., the times when the LEDs are and are not active) of illumination. The LED controller 134 can include or communicate with an oscillator oscillating at the switching frequency fₛ, such that the LEDs are activated and deactivated at the switching frequency. While connection is only shown between the LED controller 134 and a subset of the LEDs 132 shown in FIG. 8, it should be apparent that all of the LEDs could be connected to the LED controller, or, multiple LED controllers could be employed

The LEDs 132 may be arranged, for example, in a ring pattern around the first portion 102 so as to irradiate a generally radially symmetric area around the gap 106. Respective LEDs 132 may be configured to emit radiation of different wavelengths. For example, each base 114a, 114b may include LEDs 132 that emit radiation of a certain wavelength, such that radiation of a first wavelength is emitted from the LEDs contained in one base and radiation of a second wavelength is emitted from the LEDs contained in the other base. Alternatively, each base 114a, 114b may include respective LEDs configured to emit radiation at multiple wavelengths, such that, for example, one base has respective LEDs that emit radiation at a first and a second wavelength and the other base has respective LEDs that emit radiation at a third and a fourth wavelength. Regardless of whether a base 114a, 114b includes LEDs 132 emitting a uniform wavelength of radiation or a variety of wavelengths, the LEDs can be arranged so as to emit radially symmetric radiation, for example, by interleaving radially symmetric rings of LEDs of different wavelengths.

In some embodiments, sequentially irradiating a sample with radiation of respectively different wavelengths may have advantages. For example, radiation of different wavelengths may penetrate a sample to different depths. For cases where radiation penetrates relatively deep into the sample, the effect of the interaction between the radiation and the sample surface will tend to be less significant with respect to the total measurement than in cases where the radiation remains relatively shallow. As such, utilizing LEDs of differing radiation frequency can allow for characterizing the surface of a sample.

The core 100 and/or radiation source may also include an optical diffuser 136 that is disposed adjacent to the LEDs 132 and in the space between the first portion 102 and the flange 116. The diffuser 136 acts to receive the discrete outputs of the LEDs 132 and to emit more spatially uniform radiation.

In operation, the minority carrier lifetime measurement tool 122 can be configured to receive a sample s, such as a wafer of semiconductor material, so that a portion of the sample is disposed within the gap 106. In this way, a magnetic field established by the inductor 126 of a functioning marginal oscillator 124 may extend generally uniformly through the portion of the sample s disposed in the gap 106, thereby electromagnetically coupling the sample into the marginal oscillator. This electromagnetic coupling of the sample s into the oscillator 124 tends to induce eddy currents in the sample, which eddy currents dissipate energy from the oscillator 124. The magnitudes of the eddy currents and resulting energy losses are related to the conductivity σ and thickness t of the sample s, which conductivity relates to the product of the density of all of the carriers in the sample and the mobility of those carriers.

The tool 122 allows for monitoring the losses experienced by the oscillator 124 in several ways. In one case, the voltage across the marginal oscillator 124 (e.g., the measurement frequency voltage or the voltage difference between points x and y of FIG. 8) can be monitored for variation. In all cases, the marginal oscillator 124 necessarily includes a current source (not shown in FIG. 8, but discussed in more detail later) configured to supply a current sufficient to maintain the voltage across the marginal oscillator 124. This current is herein sometimes referred to as a “drive current,” and the associated current source as a “drive current source.” The output of the current source is therefore representative of losses in the oscillator 124, and this quantity is monitored. More details regarding the theory underlying such measurements are provided in U.S. Pat. No. 4,286,215 to Miller et al., the content of which is incorporated herein by reference in its entirety.

The density of minority carriers in the sample s can be modulated using the LEDs 132. The sample s can be illuminated with radiation of frequency equal to or higher than the frequency required to excite electrons from the valence band across the band gap into the conduction band (“above bandgap” radiation), thereby generating hole-electron pairs in the sample. The presence of these additional carriers results in increased conductivity (referred to as “photoconductivity”) of the sample. At the onset of irradiation, the conductivity increases monotonically, and upon cessation of irradiation, the conductivity exponentially decreases to its value in the absence of radiation (i.e., its equilibrium value). The increase in conductivity following the onset of irradiation can be described by

Δσ(t)∝μτ(1−e^{-t/τ}) (1)

where Δσ is the change in conductivity of the sample brought about by photoconductivity, μ is the sum of the hole and electron mobilities, τ is a time constant that is equal to the effective minority carrier lifetime, and t is the time elapsed since turning on the LED. It is noted that a somewhat similar equation governs the decrease in conductivity of a sample following the cessation of irradiation.

The tool 122 may be configured so as to enable several different methods of measuring minority carrier lifetime. A first method is that of photoconductive decay (PCD), in which the sample being characterized is intermittently illuminated with above bandgap radiation. The intermittent illumination can be provided at a switching (i.e., on/off) frequency fₛ that is on the order of or lower than the inverse of the (expected) effective minority carrier lifetime. Immediately after each cessation in irradiation, the decrease in conductivity σ of the sample s as a function of time can be measured. By fitting an exponential decay to these data, effective minority carrier lifetime can be determined.

The PCD method exhibits the beneficial feature of being “self-calibrating,” meaning the results obtained using this method are not relative, but are objective measurements of carrier lifetime. However, this method requires a measurement system for which response is very fast compared to the sample lifetimes. As such, while the PCD method is readily applicable to the determination of lifetime in large semiconductor single crystal ingots and/or samples having a relatively long effective minority carrier lifetime (e.g., on the order of 10 μs or more), the method tends to be less useful for measuring effective minority carrier lifetimes in samples in which the effective minority carrier lifetime is relatively short (e.g., ≦about 5 μs), since typically the sensitivity of such samples is insufficient to yield an acceptable signal-to-noise ratio.

A second method of measuring carrier lifetime that is enabled by a tool configured as described above is that described in U.S. Pat. No. 4,286,215 to Gabriel L. Miller, the content of which is incorporated herein by reference in its entirety. As with the PCD method, this method, referred to herein at the “GTAU method,” involves intermittently, at a switching frequency fₛ that is on the order of or lower than the inverse of the (expected) effective minority carrier lifetime, irradiating the sample s with above bandgap radiation. However, in the GTAU method, the conductivity σ of the sample s is measured for times that are subsequent to an activation and a deactivation of the LEDs 132 by a time which is large compared to τ. The conductivities being measured are therefore effectively steady state conductivities for an illuminated state (i.e., the conductivity when the LEDs 132 are emitting radiation) and for a non-illuminated or “darkened” state, respectively. From Equation (1), it is apparent that the difference between the steady state conductivity in the illuminated and darkened states is proportional to the product μτ. Furthermore, the increase in conductivity at the outset of irradiation of a sample will asymptotically approach a steady state value (as will the decrease in conductivity upon cessation of irradiation).

Under appropriate conditions (as discussed above), either or both the PCD method and the GTAU method may be used in conjunction with the minority carrier lifetime measurement tool 122. The data acquisition and processing components 138 can be configured to receive data from the marginal oscillator 124 (such as an indication of the voltage across the marginal oscillator, i.e., the measurement frequency voltage, or the magnitude of the drive current required to maintain the amplitude of oscillations of the oscillator at the nominal amplitude). The data acquisition and processing components 138 can also be configured to receive data from the LED controller 134 indicative of the intensity and switching frequency of the LEDs 132. All of these data can be stored for later analysis or used to provide outputs to a user regarding the conductivity of a sample.

In some embodiments, the sample s may be iteratively repositioned in the tool 122 such that different portions of the sample are disposed in the gap between the two halves of the ferrite pot core 106. The conductivity of the sample s can be remeasured for each repositioning of the sample. The data acquisition and processing components 138 can be configured to receive data regarding the movements of the sample, in addition to the conductivity data, such that minority carrier lifetime can be correlated to spatial position within the sample to create a minority carrier lifetime “map.”

As mentioned above, a tool configured in accordance with the above-described embodiments may tend to direct a magnetic field substantially uniformly across the gap defined by the first portion of the core. In some cases, this may reduce the sensitivity of measurements to spacing of the sample within the gap and relative to either portion of the first portion of the core. It is also noted that the capability of performing both the GTAU and PCD measurement methods in a single tool, as may be provided in embodiments configured in accordance with the above discussion, has significant benefits. As mentioned earlier, the GTAU method has a relatively superior SNR and is able to measure shorter minority carrier lifetimes when compared to the PCD method. However, the results of the GTAU measurements are not absolute, as they depend on light intensity. Alternatively, the PCD method, while being relatively poor in both SNR and ability to measure short carrier lifetimes, is an absolute measurement. As such, these methods can be complimentary, with the PCD method serving to calibrate the GTAU method results and the GTAU method then providing high quality measurements for short minority carrier lifetimes.

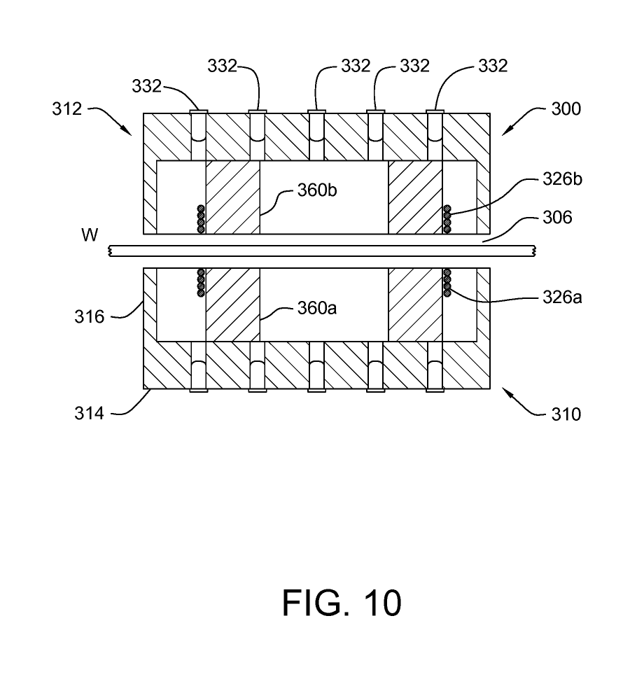

Referring to FIG. 9, therein is shown a tool 222 for measuring minority carrier lifetime, the tool being configured in accordance with another example embodiment. The tool includes a marginal oscillator 224 having an inductor 226 and a capacitor 228 and is configured to resonate at a measurement frequency fₘ that is associated with a measurement frequency voltage. The inductor 226 can be configured so as to facilitate electromagnetic coupling of a semiconductor sample s to the marginal oscillator 224, for example, by being disposed such that magnetic fields produced by the inductor extend into the sample. The core 100, as discussed above, enhances the electromagnetic coupling of the sample s into the marginal oscillator 224.

The marginal oscillator 224 necessarily includes a voltage regulation circuit 240. The voltage regulator 240 may include a comparator 242 that outputs the difference between the voltage across the oscillator 224 (as output by a rectifier 244) and a reference voltage source 246. The output from the comparator 242 is passed to an error integrator 248, which controls a current source (a drive current source) 250 to output a current (a drive current) intended to minimize the difference between the voltage across the inductor 226 and the reference voltage source 246.

Embodiments of the marginal oscillator 224 may provide enhanced performance as compared to that for previously disclosed semiconductor minority carrier lifetime measurement systems. For example, embodiments may show an improved signal-to-noise ratio (SNR) of the oscillator.

The tool 222 also includes one or more LEDs 232 in communication with a LED driver 254 configured to control the operation of the LEDs. The LED driver 254 can receive a signal from an oscillator 256 such that the switching frequency fₛ of the LEDs 232 conforms to the frequency of oscillation of the oscillator. The LEDs 232 can be driven by the LED driver 254, for example, at a switching frequency fₛ of (nominally) 100 Hz (i.e., five milliseconds “on” followed by five milliseconds “off”).

In operation, the tool 222 may be configured to receive a sample s of semiconductor material, such as a semiconductor wafer, such that the sample is electromagnetically coupled into the marginal oscillator 224 oscillating at a measurement frequency fₘ associated with a measurement frequency voltage. As the oscillator 224 transfers energy into the sample, the drive current is automatically adjusted by the voltage regulator 240, so as to maintain constant the measurement frequency voltage. As discussed above, the drive current being supplied by the drive current source 250 is representative of the sheet conductivity of the sample being measured.

The sample s can be intermittently irradiated with above bandgap radiation. The intermittence can be at a switching frequency fₛ that is on the order of or lower than the inverse of minority carrier lifetime for the sample. For each commencement and cessation of irradiation of the sample s, the conductivity of the sample will vary, as will, consequently, the load on the oscillator 224. This change in load on the oscillator 224 will cause the amplitude of the oscillations to tend to decrease, and the drive current source 250 acts to maintain (i.e., stabilize) the measurement frequency voltage across said resonant circuit constant. The drive current provided by the drive current source 250 can be continuously monitored in order to determine the sample conductivity and to determine therefrom the minority carrier lifetime of the sample.

Monitoring of the drive current can include storing, perhaps with a data acquisition device, drive current data as a function of time and the state of the LEDs 232 (e.g., the intensity of radiation emanating therefrom). The measurement frequency voltage may also be recorded for correlation with the drive current data. The drive current may be sampled at a sample rate that is higher than the inverse of minority carrier lifetime for the sample, thereby allowing for sufficient data collection to enable PCD curve-fitting for the decrease in conductivity immediately after ceasing irradiation. For example, the drive current can be digitized by a high speed analog-to-digital converter (e.g., providing 10⁶ conversions per second). In some embodiments, the sampling rate for drive current data may be synched with the oscillator 256 such that a high sampling rate is employed around the time the LEDs 232 are turned on and off, and a lower sampling rate is employed at other times.

The data collected by the tool 222 can be provided in a variety of ways. Temporal drive current data may be fit by Equation (1) and a related equation for the decay of the signal in order to obtain minority carrier lifetime directly for long lifetime samples. This is referred to as the “PCD output” (see FIG. 9). Alternatively, given that the drive current modulation is proportional to minority carrier lifetime, the drive current itself can be appropriately amplified (with, e.g., a lock-in amplifier synchronized with the oscillator 256) so as to indicate minority carrier lifetime. This output is referred to as the “GTAU output.” As still another alternative, the conductivity of the sample (from which the GTAU output was derived”) can be reported. This output is referred to as the “sheet conductance output,” And is calculated by using a single sample of known sheet conductance. It is noted that any or all of these outputs can be provided essentially simultaneously for a single sample.

Overall, a system configured in accordance with the above-described embodiments may enable the measurement of semiconductor minority carrier lifetimes, from less than one tenth of a microsecond to milliseconds, with each measurement taking of the order of half of a second. Measurements may be performed using the PCD method and the GTAU method, with the PCD method providing inherent calibration and the GTAU method facilitating short lifetime measurements and providing improved SNR. Sheet conductance may also be reported, and outputs from all three measurements (PCD, GTAU, and sheet conductance) may be available to a user.

Referring to FIG. 10, therein is shown a schematic cross-sectional view of a core 300 for use as part of a tool for measuring minority carrier lifetimes (e.g., the tool 122 of FIG. 2), the core being configured in accordance with another example embodiment. The core 300 can include opposing first 310 and second parts 312 that are spaced apart to form a gap 306 configured to receive a wafer w for which minority carrier lifetime is to be measured. Each of the first and second parts 310, 312 can have a generally planar base 314 and a generally annular flange 316. LEDs 332 may extend through the base 314, as discussed earlier.

Each part 310, 312 can also include a respective tubular portion 360a, 360b that extends from the base 314 and is disposed radially inside of the flange 316. The tubular portions 360a, 360b may be transparent to light emitted by the LEDs 332 (or to whatever radiation is used to irradiate the wafer w). For example, the tubular portions 360a, 360b may be formed of a transparent plastic material. A conductor, such as a wire 326a, can be coiled around the tubular portion 360a, and another conductor, such as a wire 326b, can be coiled around the tubular portion 360b. The wires 326a, 326b may therefore form inductors when connected to a variable power source (not shown). The wires 326a, 326b can be connected in parallel to the power source, and may be configured such that the magnetic field produced by each wire aligns with that produced by the other. In this way, the magnetic fields can supplement one another rather than opposing one another. In some embodiments, the wires 326a, 326b may be wound around the respective tubular portions 360a, 360b at locations close to the gap 306, thereby increasing the uniformity of the aggregate magnetic field across the gap.

Several alternative embodiments of the invention may be possible while maintaining the principles (and benefits) of the measurement system described here. Specifically, alternative configurations of the ferromagnetic core may include, e.g., opposing U-shaped or E-shaped cores, instead of the opposing split cup core described here. In evaluating the appropriateness of these (and other) alternative embodiments there are three key parameters that need to be evaluated; the tightness of the inductive coupling to the semiconductor sample, the uniformity of the light source, and the shielding to signals arising from any semiconductor material outside the desired measurement area. It is maintained here that the split cup core embodiment may enable advantages with respect to one or more of these key parameters as compared to alternative configurations. Therefore, it is to be understood that the inventions are not to be limited to the specific embodiments disclosed and that modifications and other embodiments are intended to be included within the scope of the appended claims. Although specific terms are employed herein, they are used in a generic and descriptive sense only and not for purposes of limitation.

That which is claimed:

1. An apparatus comprising:
a resonant circuit including an inductor and a capacitor and configured to resonate at a measurement frequency;
a ferromagnetic core including
a first portion that defines a gap and is configured to direct therealong a magnetic field established by said inductor, such that lateral spreading of the magnetic field outside of said first portion is inhibited, and to direct the magnetic field generally uniformly across the gap; and
a second portion configured to direct the magnetic field therealong and, in conjunction with said first portion, into a closed loop; and
a radiation source configured to irradiate an area proximal to the gap defined by said first portion of said ferromagnetic core.

2. The apparatus of claim 1, wherein said inductor includes at least one coil that extends circumferentially around said first portion.

3. The apparatus of claim 1, wherein said radiation source is configured to irradiate an area around the gap that is symmetric across a longitudinal axis defined by said first portion.

4. The apparatus of claim 1, wherein said first portion defines a longitudinal axis, and said ferromagnetic core is generally radially symmetric about the longitudinal axis.

5. The apparatus of claim 1, wherein said radiation source includes at least two light emitting diodes configured to emit radiation of respectively different wavelengths.

6. The apparatus of claim 1, wherein said ferromagnetic core includes opposing first and second parts, said first part forming at least part of said first and second portions and said second part forming at least part of said first and second portions.

7. The apparatus of claim 6, wherein said first and second parts are generally symmetrical across a plane directed along the gap defined by said first portion of said ferromagnetic core.

8. The apparatus of claim 6, wherein said first and second parts respectively include elongated bases, a central post extending from each of said elongated bases, and a pair of side posts extending from each of said elongated bases on opposing sides of, and generally parallel to, said central post, such that each of said first and second parts generally forms an “E” shape, said first portion including said central posts and said second portion including said side posts.

9. The apparatus of claim 6, wherein said first and second parts respectively include generally planar bases, said first portion extends generally perpendicularly from said bases, and said second portion forms a generally annular flange extending generally perpendicularly from said bases and circumferentially around said first portion.

10. The apparatus of claim 9, wherein said second portion defines a gap that is aligned with the gap defined by said first portion.

11. The apparatus of claim 9, wherein said radiation source includes a light emitting diode that extends through one of said bases and is disposed between said first portion and said flange formed by said second portion.

12. The apparatus of claim 9, wherein said radiation source includes at least two light emitting diodes that extend through respective ones of said bases and are respectively disposed between said first portion and said flange formed by said second portion.

13. The apparatus of claim 9, wherein said radiation source includes a plurality of light emitting diodes disposed circumferentially around said first portion and extending through one of said bases between said first portion and said flange formed by said second portion.

14. The apparatus of claim 13, wherein said radiation source includes another plurality of light emitting diodes disposed circumferentially around said first portion and extending through another of said bases between said first portion and said flange formed by said second portion.

15. The apparatus of claim 1, wherein said radiation source is configured to emit radiation intermittently at a switching frequency.

16. The apparatus of claim 15, wherein said apparatus is configured to receive a sample of semiconductor material in the gap defined by said first portion of said ferromagnetic core and said radiation source is configured to intermittently irradiate the sample, the radiation being configured to cause photoconductivity in the sample and the switching frequency being on the order of or lower than the inverse of minority carrier lifetime for the sample, and wherein said resonant circuit is associated with a measurement frequency voltage and includes a drive current source configured to provide a drive current that is adjustable so as to maintain the measurement frequency voltage across said resonant circuit constant.

17. The apparatus of claim 16, further comprising a data acquisition system configured to collect drive current values at times subsequent to commencing and halting irradiation of the sample by more than the inverse of minority carrier lifetime of the sample.

18. The apparatus of claim 17, wherein said data acquisition system is further configured to collect drive current values at a data collection frequency that is higher than the inverse of minority carrier lifetime for the sample and at times immediately subsequent to commencing and halting irradiation of the sample.

19. An apparatus comprising:
a ferromagnetic core including
a first portion that defines a gap and is configured to direct therealong a magnetic field established by an inductor coiled around said first portion, such that lateral spreading of the magnetic field outside of said first portion is inhibited, and to direct the magnetic field generally uniformly across the gap; and
a second portion configured to direct the magnetic field therealong and, in conjunction with said first portion, into a closed loop; and
a radiation source integrated into said ferromagnetic core.

20. The apparatus of claim 19, wherein said radiation source is configured to irradiate a radially symmetric area around the gap defined by said first portion of said ferromagnetic core.

21. The apparatus of claim 19, wherein said first portion defines a longitudinal axis, and said ferromagnetic core is generally radially symmetric about the longitudinal axis.

22. The apparatus of claim 19, wherein said radiation source includes at least two light emitting diodes configured to emit radiation of respectively different wavelengths.

23. The apparatus of claim 19, wherein said apparatus is configured to receive a sample of semiconductor material in the gap defined by said first portion of said ferromagnetic core such that said radiation source can irradiate the sample.

24. The apparatus of claim 19, wherein said ferromagnetic core includes opposing first and second parts, said first part forming at least part of said first and second portions and said second part forming at least part of said first and second portions.

25. The apparatus of claim 24, wherein said first and second parts are generally symmetrical across a plane directed along the gap defined by said first portion of said ferromagnetic core.

26. The apparatus of claim 24, wherein said first and second parts respectively include elongated bases, a central post extending from each of said elongated bases, and a pair of side posts extending from each of said elongated bases on opposing sides of, and generally parallel to, said central post, such that each of said first and second parts generally forms an “E” shape, said first portion including said central posts and said second portion including said side posts.

27. The apparatus of claim 24, wherein said first and second parts respectively include generally planar bases, said first portion extends generally perpendicularly from said bases, and said second portion forms a generally annular flange extending generally perpendicularly from said bases and circumferentially around said first portion.

28. The apparatus of claim 27, wherein said second portion defines a gap that is aligned with the gap defined by said first portion.

29. The apparatus of claim 27, wherein said radiation source includes a light emitting diode that extends through one of said bases and is disposed between said first portion and said flange formed by said second portion.

30. The apparatus of claim 27, wherein said radiation source includes at least two light emitting diodes that extend through respective ones of said bases and are respectively disposed between said first portion and said flange formed by said second portion.

31. The apparatus of claim 27, wherein said radiation source includes a plurality of light emitting diodes disposed circumferentially around said first portion and extending through one of said bases between said first portion and said flange formed by said second portion.

32. The apparatus of claim 31, wherein said radiation source includes another plurality of light emitting diodes disposed circumferentially around said first portion and extending through another of said bases between said first portion and said flange formed by said second portion.

33. A method comprising:
providing an apparatus including
a resonant circuit including an inductor and a capacitor and configured to resonate at a measurement frequency associated with a measurement frequency voltage across the resonant circuit;
a ferromagnetic core including
a first portion that defines a gap and is configured to direct therealong a magnetic field established by the inductor, such that lateral spreading of the magnetic field outside of the first portion is inhibited, and to direct the magnetic field generally uniformly across the gap; and
a second portion configured to direct the magnetic field therealong and, in conjunction with the first portion, into a closed loop; and
a radiation source configured to irradiate an area proximal to the gap defined by the first portion of the ferromagnetic core;
electromagnetically coupling a sample into the resonant circuit, a first portion of the sample being disposed in the gap such that a magnetic field established by the inductor extends generally uniformly through the first portion of the sample;
adjusting a drive current of the resonant circuit to maintain constant the measurement frequency voltage; and
intermittently, at a switching frequency, irradiating the sample in an area proximal to the first portion with radiation configured to cause photoconduction in the sample, the switching frequency being on the order of or lower than the inverse of minority carrier lifetime for the sample.

34. The method of claim 33, further comprising determining a minority carrier lifetime for the sample.

35. The method of claim 34, wherein said determining a minority carrier lifetime for the sample includes measuring the drive current both while irradiating the sample and when the sample is not being irradiated.

36. The method of claim 35, wherein said measuring the drive current further includes sampling the drive current at a sample rate that is higher than the inverse of minority carrier lifetime for the sample and at times immediately subsequent to commencing and halting irradiation of the sample, said method further comprising determining a functional approximation for temporal drive current data measured after halting irradiation of the sample and within a time equal to the inverse of minority carrier lifetime for the sample.

37. The method of claim 35, wherein said measuring the drive current includes measuring the quasi-steady state drive current after commencing and halting irradiation of the sample to find a difference therebetween, further comprising scaling the difference and providing the scaled difference as an output.

38. The method of claim 33, wherein said intermittently irradiating the sample includes intermittently irradiating the sample with radiation of a first characteristic wavelength and subsequently intermittently irradiating the sample with radiation of a second characteristic wavelength that is different from the first characteristic wavelength.

39. The method of claim 33, further comprising repeatedly repositioning the sample such that different portions of the sample are disposed in the gap defined by the first portion of the ferromagnetic core, and wherein said measuring the drive current includes repeatedly measuring the drive current in response to each repeated repositioning of the sample.

40. The method of claim 33, wherein said providing an apparatus includes providing an apparatus including a ferromagnetic core having opposing first and second parts, said first part forming at least part of said first and second portions and said second part forming at least part of said first and second portions, wherein said first and second parts respectively include generally planar bases, said first portion extends generally perpendicularly from said bases, and said second portion forms a generally annular flange extending generally perpendicularly from said bases and circumferentially around said first portion.

41. The method of claim 40, wherein said providing an apparatus includes providing an apparatus including a radiation source having a plurality of light emitting diodes disposed circumferentially around said first portion and extending through one of said bases between said first portion and said flange formed by said second portion.

42. The method of claim 33, wherein said providing an apparatus includes providing an apparatus including a ferromagnetic core having opposing first and second parts that respectively include elongated bases, a central post extending from each of said elongated bases, and a pair of side posts extending from each of said elongated bases on opposing sides of, and generally parallel to, said central post, such that each of said first and second parts generally forms an “E” shape, said first portion including said central posts and said second portion including said side posts.

43. An apparatus comprising:
a ferromagnetic core including opposing first and second parts that define a gap therebetween, each of said first and second parts including
a base;
a generally annular flange extending from said base; and
a tubular portion extending from said base and radially inside said flange;
a first conductor coil that extends around said tubular portion associated with said first part;
a second conductor coil that extends around said tubular portion associated with said second part; and
a radiation source configured to irradiate at least a portion of the gap defined between said first and second parts,
wherein said first and second conductor coils are configured to be connected in parallel to a variable power source, such that a magnetic field generated by said first conductor coil is generally aligned with a magnetic field generated by said second conductor coil.

43. The apparatus of claim 43, wherein said tubular portion is transparent to radiation emitted from said radiation source.
